(19) United States
(12) Patent Application Publication
(10) Pub. No.: US 2015/0355749 A1
(43) Pub. Date: Dec. 10, 2015

(54) DISPLAY DEVICE, TOUCH SCREEN DEVICE, AND TOUCH DRIVER FOR THE SAME

(71) Applicant: Samsung Display Co., Ltd., Yongin-City (KR)

(72) Inventor: Byung Chan Min, Yongin-si (KR)

(21) Appl. No.: 14/539,833

(22) Filed: Nov. 12, 2014

(30) Foreign Application Priority Data
Jun. 10, 2014 (KR) 10-2014-0070248

(51) Int. Cl. G06F 3/044; G06F 3/047; H01L 27/02; G06F 3/041

(52) U.S. Cl. CPC G06F 3/044; G06F 3/0412; G06F 3/047; H01L 27/0255

(57) ABSTRACT

A display device, touch screen device, and touch driver for the same are disclosed. In one aspect, the display device includes a display substrate including a plurality of pixels and having a front surface, a touch substrate formed over the front surface, a flexible printed circuit substrate electrically connected to the touch substrate, and a touch driver formed over the flexible printed circuit substrate. The touch driver includes a touch controller configured to receive a touch control signal, a clamping circuit configured to substantially block an overcurrent voltage having a voltage level substantially equal to or higher than a predetermined clamping voltage, and at least one transient voltage suppressor (TVS) electrically connected to at least one voltage source including a voltage applied to the touch controller. The at least one TVS is also electrically connected to an electrical ground so as to discharge the overcurrent.

### CROSS-REFERENCE TO RELATED APPLICATION

This application claims priority to and the benefit of Korean Patent Application No. 10-2014-0070248 filed in the Korean Intellectual Property Office on Jun. 10, 2014, the entire contents of which are incorporated herein by reference.

### BACKGROUND

1. Field

The described technology generally relates to a display device, a touch screen device, and a touch driver for the same.

2. Description of the Related Technology

Display devices such as liquid crystal displays (LCDs) and organic light-emitting diode (OLED) displays include a plurality of scanning lines and a plurality of data lines which are connected to a plurality of pixels. The pixels are formed at intersecting points of the scanning lines and the data lines. Scanning signals having a gate-on voltage are sequentially applied to the scanning lines and data signals corresponding to the scanning signals having the gate-on voltage are applied to the data lines, thereby transmitting image data to the pixels.

A touch screen device is an input device that receives a user's command by recognizing a touch position of the user. The touch screen device is provided on a front side of the display device so as to identify a position touched by a finger(s) or an object to determine an input signal. Among the ways of implementing the touch screen device, capacitance measurement is usually employed. Capacitive touch screen devices sense changes of electrostatic capacitance formed between an electrode and a conductive object such as a user's finger, and sense the change of electrostatic capacitance of a contact position by sequentially applying sensing signals to a plurality of sensing lines.

### SUMMARY OF CERTAIN INVENTIVE ASPECTS

One inventive aspect is a display device including: a display substrate configured to include a plurality of pixels; a touch substrate formed on an front surface of the display substrate; a flexible printed circuit substrate connected to the touch substrate; and a touch driver formed on the flexible printed circuit substrate, wherein the touch driver includes: a touch controller; a clamping circuit configured to block an overcurrent caused by electrical overstress or electrostatic discharge transferred through a wire for a touch control signal that is applied from the outside to the touch controller; and a transient voltage suppressor connected to a wire for a power source voltage that is applied from the outside to the touch controller, to discharge an overcurrent to a ground power source.

The power source voltage can include: a first power source voltage configured to supply a power to a logic circuit of the touch controller; and a second power source voltage configured to supply a driving power of the touch controller.

The transient voltage suppressor can include a first TVS diode having one end that is connected to a wire of the first power source voltage and the other end that is connected to a ground power source.

The transient voltage suppressor can further include a second TVS diode having one end that is connected to a wire of the second power source voltage and the other end that is connected to the ground power source.

The display device can further include a third TVS diode having one end that is connected to a wire for an event signal that is applied from the outside to the touch controller and the other end that is connected to the ground power source.

The touch substrate can include: a plurality of driving electrodes; a plurality of sensing electrodes; a plurality of first sensing wires connected to the driving electrodes; a plurality of second sensing wires connected to the sensing electrodes; and a ground wire formed in a loop-like shape at an outer region of the driving electrodes and the sensing electrodes.

The first sensing wires, the second sensing wires and the ground wire can be connected to the touch controller.

The display device can further include a fourth TVS diode having one end that is connected to one end of the ground wire and the other end that is connected to the ground power source.

The display device can further include a fifth TVS diode having one end that is connected to the other end of the ground wire and the other end that is connected to the ground power source.

Another aspect is a touch screen device including: a touch substrate configured to include a plurality of driving electrodes and a plurality of sensing electrodes; and a touch driver connected to the touch substrate that is connected to the flexible printed circuit substrate, wherein the touch driver includes: a touch controller; a clamping circuit configured to block an overcurrent caused by electrical overstress or electrostatic discharge transferred through a wire for a touch control signal that is applied from the outside to the touch controller; and a transient voltage suppressor connected to a wire for a power source voltage that is applied from the outside to the touch controller, to discharge an overcurrent to a ground power source.

The power source voltage can include: a first power source voltage configured to supply a power to a logic circuit of the touch controller; and a second power source voltage configured to supply a driving power of the touch controller.

The transient voltage suppressor can include a first TVS diode having one end that is connected to a wire of the first power source voltage and the other end that is connected to a ground power source.

The transient voltage suppressor can further include a second TVS diode having one end that is connected to a wire of the second power source voltage and the other end that is connected to the ground power source.

The touch screen device can further include a third TVS diode having one end that is connected to a wire for an event signal that is applied from the outside to the touch controller and the other end that is connected to the ground power source.

The touch substrate can further include: a plurality of first sensing wires connected to the driving electrodes; a plurality of second sensing wires connected to the sensing electrodes; and a ground wire formed in a loop-like shape at an outer region of the driving electrodes and the sensing electrodes, and the first sensing wires, the second sensing wires, and the ground wire can be connected to the touch controller.

The touch screen device can further include a fourth TVS diode having one end that is connected to one end of the ground wire and the other end that is connected to the ground power source.

The touch screen device can further include a fifth TVS diode having one end that is connected to the other end of the ground wire and the other end that is connected to the ground power source.

Another aspect is a touch driver for controlling a driving of a touch screen device, including: a touch controller; a clamping circuit configured to block an overcurrent caused by electrical overstress or electrostatic discharge transferred through a wire for a touch control signal that is applied from the outside to the touch controller; and a transient voltage suppressor connected to a wire for a power source voltage that is applied from the outside to the touch controller, to discharge an overcurrent to a ground power source.

The transient voltage suppressor can include: a first TVS diode having one end that is connected to a wire of the first power source voltage and the other end that is connected to a ground power source; and a second TVS diode having one end that is connected to a wire of the second power source voltage and the other end that is connected to the ground power source.

The touch driver can further include a third TVS diode having one end that is connected to a wire for an event signal that is applied from the outside to the touch controller, and the other end that is connected to the ground power source.

Another aspect is a display device comprising a display substrate including a plurality of pixels and having a front surface, a touch substrate formed over the front surface, a flexible printed circuit substrate electrically connected to the touch substrate, and a touch driver formed over the flexible printed circuit substrate. The touch driver comprises a touch controller configured to receive a touch control signal, a clamping circuit configured to substantially block an overcurrent voltage having a voltage level substantially equal to or higher than a predetermined clamping voltage, and at least one transient voltage suppressor (TVS) electrically connected to i) at least one voltage source including a voltage applied to the touch controller and ii) an electrical ground so as to discharge the overcurrent.

In the above display device, the touch controller includes a logic circuit, wherein the at least one voltage source includes first and second voltage sources configured to respectively supply voltages to the logic circuit and the touch controller except for the logic circuit.

In the above display device, the at least one TVS includes a first TVS diode electrically connected to the first voltage source and the electrical ground.

In the above display device, the at least one TVS further includes a second TVS diode electrically connected to the second voltage source and the electrical ground.

The above display device further comprises a third TVS diode electrically connected to an event signal wire and the electrical ground, wherein the event signal wire is configured to transfer an event signal to the touch controller.

In the above display device, the touch substrate includes a plurality of driving electrodes, a plurality of sensing electrodes, a plurality of first sensing wires electrically connected to the driving electrodes, a plurality of second sensing wires electrically connected to the sensing electrodes, and a ground wire having a loop-like shape and formed at an outer region of the driving electrodes and the sensing electrodes.

In the above display device, the first and second sensing wires and the ground wire are electrically connected to the touch controller.

The above display device further comprises a fourth TVS diode electrically connected to one end of the ground wire and the electrical ground.

The above display device further comprises a fifth TVS diode electrically connected to the other end of the ground wire and the electrical ground.

Another aspect is a touch screen device comprising a touch substrate including a plurality of driving electrodes and a plurality of sensing electrodes, and a touch driver electrically connected to the touch substrate. The touch driver comprises a touch controller configured to receive a touch control signal, a clamping circuit configured to substantially block an overcurrent voltage having a voltage level substantially equal to or higher than a predetermined clamping voltage, and at least one transient voltage suppressor (TVS) electrically connected to i) at least one voltage source including a voltage applied to the touch controller and ii) an electrical ground so as to discharge the overcurrent.

In the above touch screen device, the touch controller includes a logic circuit, and wherein the voltage source includes first and second voltage sources configured to respectively supply voltages to the logic circuit and the touch controller except for the logic circuit.

In the above touch screen device, the at least one TVS includes a first TVS diode electrically connected to the first voltage source and the electrical ground.

In the above touch screen device, the at least one TVS further includes a second TVS diode electrically connected to the second voltage source and the electrical ground.

The above touch screen device further comprises a third TVS diode electrically connected to an event signal wire and the electrical ground, wherein the event signal wire is configured to transfer an event signal to the touch controller.

In the above touch screen device, the touch substrate further includes a plurality of first sensing wires electrically connected to the driving electrodes, a plurality of second sensing wires electrically connected to the sensing electrodes, and a ground wire having a loop-like shape and formed at an outer region of the driving electrodes and the sensing electrodes, wherein the first and second sensing wires and the ground wire are electrically connected to the touch controller.

The above touch screen device further comprises a fourth TVS diode electrically connected to one end of the ground wire and the electrical ground.

The above touch screen device further comprises a fifth TVS diode electrically connected to the other end of the ground wire and the electrical ground.

Another aspect is a touch driver for controlling a driving of a touch screen device, the touch driver comprising a touch controller configured to receive a touch control signal, a clamping circuit configured to substantially block an overcurrent voltage having a voltage level substantially equal to or higher than a predetermined clamping voltage, and at least one transient voltage suppressor (TVS) electrically connected to i) at least one voltage source including a voltage applied to the touch controller and ii) an electrical ground so as to discharge the overcurrent.

In the above touch driver, the at least one TVS includes a first TVS diode electrically connected to the first voltage source and the electrical ground, and a second TVS diode electrically connected to the second voltage source and the electrical ground.

The above touch driver further comprises a third TVS diode electrically connected to an event signal wire and the electrical ground, wherein the event signal wire is configured to transfer an event signal to the touch controller.

According to at least one of the disclosed embodiments, it is possible to protect the touch screen device against electrical overstress and electrostatic discharge.

### BRIEF DESCRIPTION OF THE DRAWINGS

FIG. 1 is a schematic top plan view illustrating a display device and a touch screen device according to an exemplary embodiment.

FIG. 2 is a schematic top plan view illustrating a display device according to an exemplary embodiment.

FIG. 3 is a schematic top plan view illustrating a touch screen device according to an exemplary embodiment.

FIG. 4 is a top plan view illustrating a touch substrate of a touch screen device according to an exemplary embodiment.

FIG. 5 is a block diagram illustrating a second connector of a touch screen device according to an exemplary embodiment.

FIG. 6 is a block diagram illustrating a second connector of a touch driver device according to an exemplary embodiment.

FIG. 7 is a block diagram illustrating a portion connected between a touch substrate and a second flexible printed circuit substrate in a touch screen device according to an exemplary embodiment.

FIG. 8 is a graph illustrating a test result of measuring the noise of a signal before and after passing through a clamping circuit in a touch screen device according to an exemplary embodiment.

### DETAILED DESCRIPTION OF CERTAIN INVENTIVE EMBODIMENTS

As touch screen devices are provided on a front surface of display panels, noise caused by data signals and scan signals of the display panel can be generated in detection signals of touch screen devices. Further, the touch screen device can be easily exposed to external electrical overstress (EOS) or electrostatic discharge (ESD), and the like. In this case, internal circuits can be damaged or even stop functioning. ESD or EOS frequently occurs during the manufacturing process of a touch screen device or a display device.

Hereinafter, exemplary embodiments will be described in detail with reference to the attached drawings such that the described technology can be easily put into practice by those skilled in the art. As those skilled in the art would realize, the described embodiments can be modified in various different ways, all without departing from the spirit or scope of the described technology.

In addition, in various exemplary embodiments, the same constituent elements are denoted by the same reference numerals and are representatively described in an exemplary embodiment, and different elements from the elements of the exemplary embodiment are described in other exemplary embodiments.

In the drawings and this specification, parts or elements that are not related to the description hereof are omitted in order to clearly describe the described technology, and the same or like constituent elements are designated by the same reference numerals throughout the specification.

Throughout this specification and the claims that follow, when it is described that an element is “coupled” to another element, the element can be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements. In this disclosure, the term “substantially” includes the meanings of completely, almost completely or to any significant degree under some applications and in accordance with those skilled in the art. Moreover, “formed on” can also mean “formed over.” The term “connected” can include an electrical connection.

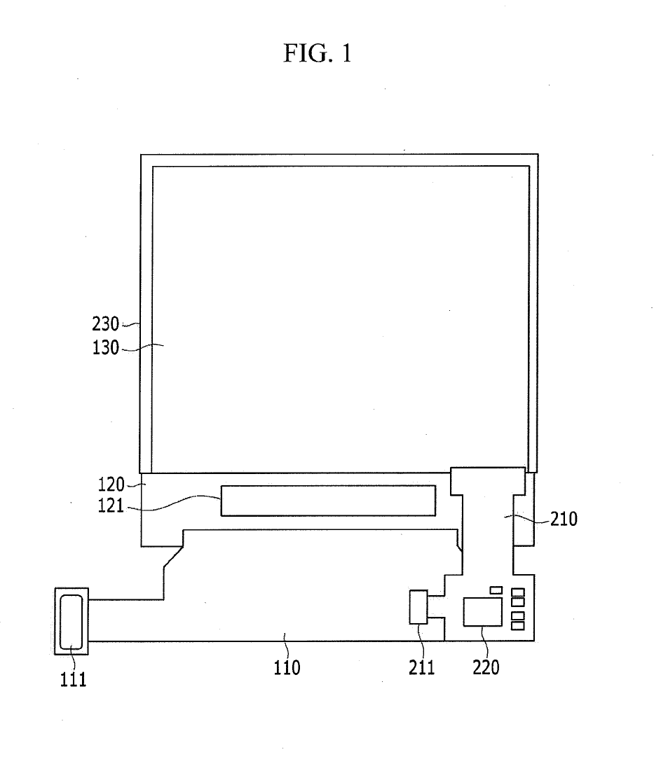

First, schematic configurations of a display device and a touch screen device will be described with reference to FIG. 1 to FIG. 3.

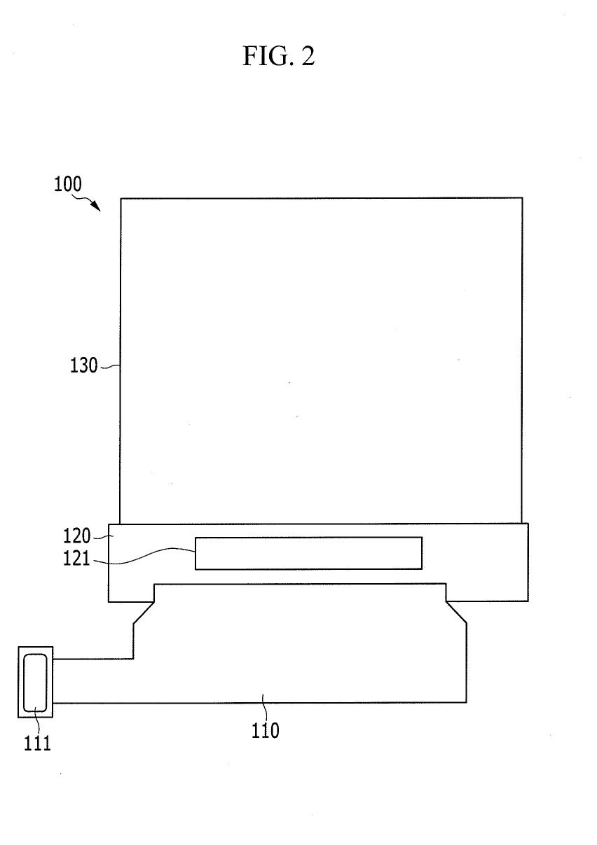

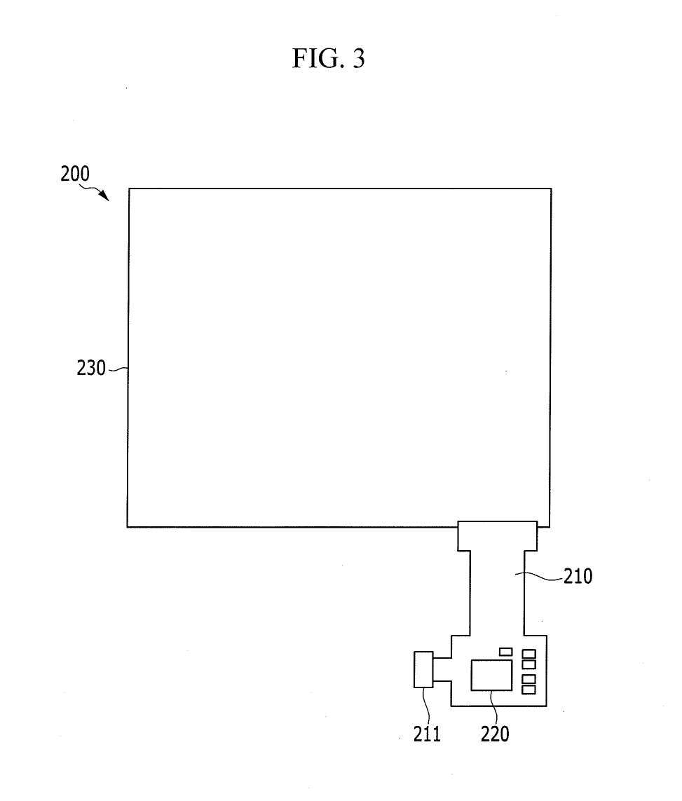

FIG. 1 is a schematic top plan view illustrating a display device and a touch screen device according to an exemplary embodiment. FIG. 2 is a schematic top plan view illustrating a display device according to an exemplary embodiment. FIG. 3 is a schematic top plan view illustrating a touch screen device according to an exemplary embodiment.

Referring to FIG. 1 to FIG. 3, a display device 100 includes a first flexible printed circuit substrate 110, a driving substrate 120, and a display substrate 130.

A plurality of pixels (not shown) are formed in the display substrate 130. Each of the pixels can include an organic light-emitting diode (OLED). For example, the display device can be an OLED display using a plurality of pixels each including an OLED. Herein, the display device is assumed to be, but is not limited to, an OLED display. For example, the display device can be a liquid crystal display (LCD), an electrophoretic display, a field emission display (FED), or a plasma display panel (PDP).

A pixel driver 121 for driving the pixels is formed in the driving substrate 120. Herein, the driving substrate 120 and the display substrate 130 are illustrated as separate units, but can be provided as a single substrate. For example, a substantially central area corresponding to the display substrate 130 and a peripheral area corresponding to the driving substrate 120 are formed on one substrate, the pixels are formed in substantially the central area, and the pixel driver 121 is formed in the peripheral area.

A first connector 111 for receiving a signal from the outside is formed on the first flexible printed circuit substrate 110. Driving signals of the pixels, touch control signals, power source voltages, and the like are input through the first connector 111. The first flexible printed circuit substrate 110 is connected to the driving substrate 120 so as to transfer the driving signals, the power source voltages, and the like to the pixel driver 121.

A touch screen device 200, includes a second flexible printed circuit substrate 210 and a touch substrate 230.

The touch substrate 230 is formed on a front surface of the display substrate 130. The touch substrate 230 can be embodied in various types such as a resistive type, a capacitive type, an ultrasonic type, a photo-sensor type, and an electromagnetic induction type. Herein, a capacitive type of touch screen device is assumed to be used.

A plurality of electrodes for detecting a touch are formed in the touch substrate 230. The electrodes can include a plurality of driving electrodes and a plurality of sensing electrodes, which will be described later.

A second connector 211 and a touch driver 220 are formed in the second flexible printed circuit substrate 210. The second connector 211 is connected to the first flexible printed circuit substrate 210. The second connector 211 transfers power source voltages and touch control signals between the first flexible printed circuit substrate 110 and the second flexible printed circuit substrate 210. The power source voltages and the touch control signal transferred through the second connector 211 are transferred to the touch driver 220. The second flexible printed circuit substrate 210 is connected to the touch substrate 230. The touch driver 220 applies a touch detection signal to the electrodes formed in the touch substrate 230 based at least in part on a touch control signal, and receives a sensing signal in response to the touch detection signal to detect a touched position.

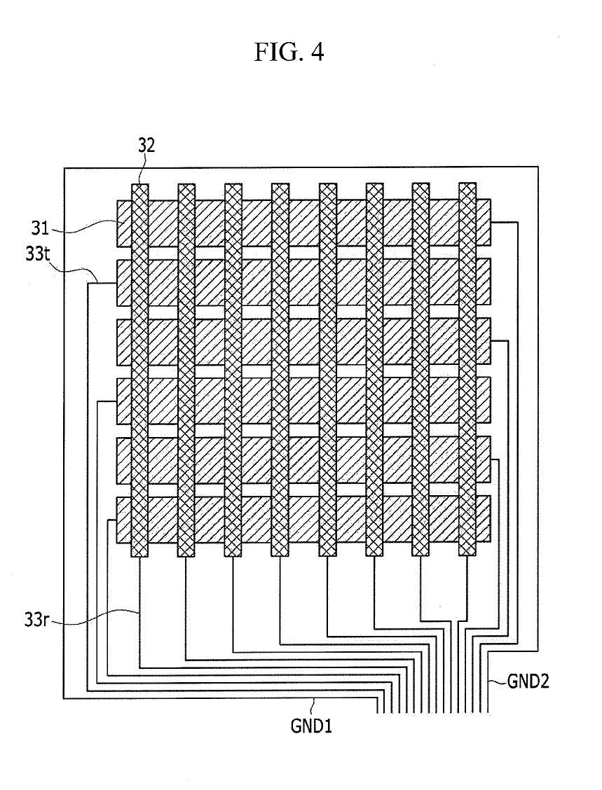

FIG. 4 is a top plan view illustrating the touch substrate 230 according to an exemplary embodiment.

Referring to FIG. 4, the touch substrate 230 includes a plurality of driving electrodes 31 formed on a transparent substrate (not shown), and a plurality of sensing electrodes 32 formed on the driving electrodes 31. An insulating layer (not shown) can be formed between the driving electrodes 31 and the sensing electrodes 32.

The driving electrodes 31 is formed in a first direction, and the sensing electrode 32 is formed in a second direction crossing the first direction. The driving electrodes 31 and the sensing electrodes 32 can be formed of a transparent conductive film such as indium tin oxide (ITO). Alternatively, the driving electrodes 31 and the sensing electrodes 32 can be formed of a metal mesh, carbon nanotubes (CNT), or the like.

The insulating layer is interposed between the driving electrodes 31 and the sensing electrodes 32 so as to separate the electrodes 31 and 32 from each other. An inorganic insulating material such as a silicon oxide (SiOx) or a silicon nitride (SiNx) can be used as the insulating layer

Alternatively, as the insulating layer, an organic insulating material such as a cellulose derivative, an olefin-based resin, an acryl-based resin, a vinyl chloride-based resin, a styrene-based resin, a polyester-based resin, a polyamide-based resin, a polycarbonate-based resin, a polycycloolefin resin, or an epoxy resin can be used.

The driving electrodes 31 and the sensing electrodes 32 are separated from each other by the insulating layer so as to form a capacitance therebetween.

The driving electrodes 31 are connected to a plurality of first sensing wires 33t, and the sensing electrodes 32 are connected to a plurality of second sensing wires 33r. The first sensing wires 33t and the second sensing wires 33r are connected to the touch driver 220. The touch driver 220 applies the touch detection signal to the driving electrodes 31 through the first sensing wires 33t and receives the sensing signal indicating a change in the capacitance of the sensing electrodes 32 through the second sensing wires 33r, so as to detect a touch position.

The touch substrate 230 further includes ground wires GND1 and GND2. The ground wires GND1 and GND2 are formed at an outer region of the driving electrodes 31 and the sensing electrodes 32, but are not limited thereto. For example, the ground wires GND1 and GND2 are formed along an edge of the touch substrate 230 in a loop-like shape so as to surround the driving electrodes 31 and the sensing electrodes 32. One ends of the ground wires GND1 and GND2 are formed in the loop-like shape and are connected to the touch driver 220. The ground wires GND1 and GND2 can be electrically connected to a ground power source so as to remove the electrostatic discharge transferred from the outside. The ground wires GND1 and GND2 can be electrically connected to a ground power supply of the second flexible printed circuit substrate 210.

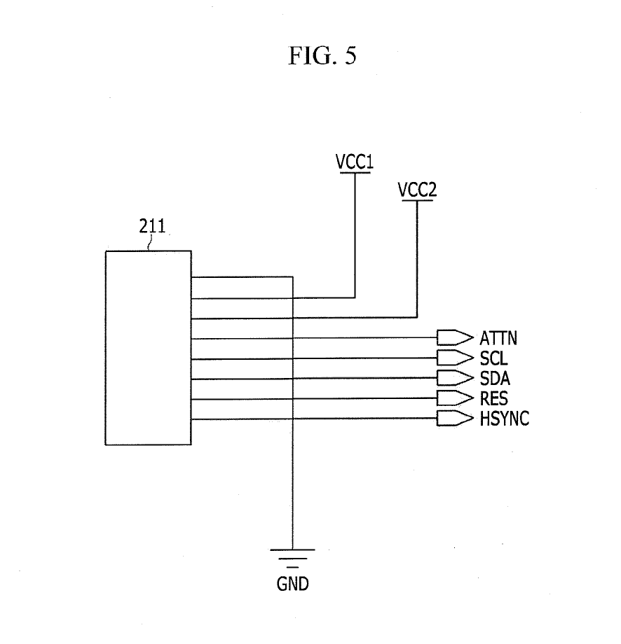

Hereinafter, a configuration for protecting a touch screen device against electrostatic discharge and electrical overstress will be described with reference to FIG. 5 to FIG. 7.

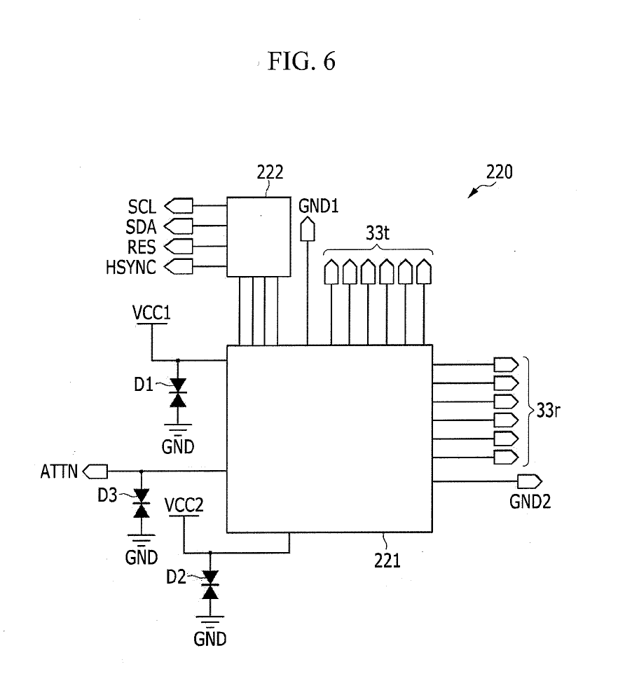

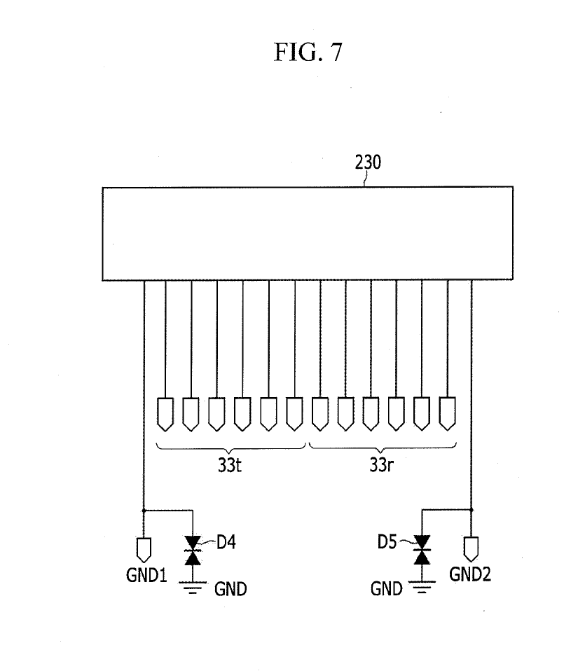

FIGS. 5 and 6 are block diagrams illustrating the second connector 211 of the touch screen device 200 according to an exemplary embodiment. FIG. 7 is a block diagram illustrating a portion connected between the touch substrate 230 and the second flexible printed circuit substrate 210 in the touch screen device 200 according to an exemplary embodiment.

Referring to FIG. 5 to FIG. 7, the second connector 211 transfers the power source voltage and the touch control signal between the first and second flexible printed circuit substrates 110 and 210.

The touch control signal, which serves to control the driving of the touch driver 220, includes an event signal ATTN, a clock signal SCL, a coordinate value data signal SDA, a reset signal RES, a synchronization signal HSYNC, and the like. The power source voltage includes first and second power source voltages VCC1 and VCC2, a ground power source GND, and the like.

The touch driver 220 includes a touch controller 221, a clamping circuit 222 and first to third transient voltage suppressors D1 to D3.

The touch controller 221 serves to control a general operation of the touch screen device 200.

The clamping circuit 222 is connected between the second connector 211 and the touch controller 221. The clamping circuit 222 transmits the clock signal SCL, the coordinate value data signal SDA, the reset signal RES, and the synchronization signal HSYNC that are applied from the outside, to the touch controller 221. Herein, the clamping circuit 222, which serves to block a signal that is substantially equal to or higher than a predetermined clamping voltage, substantially blocks an overcurrent caused by electrical overstress or electrostatic discharge transferred through the wires for the clock signal SCL, the coordinate value data signal SDA, the reset signal RES, and the synchronization signal HSYNC. The clamping circuit 222 can be provided as a low pass filter.

In this exemplary embodiment, the clock signal SCL, the coordinate value data signal SDA, the reset signal RES, and the synchronization signal HSYNC are described to be applied to the clamping circuit 222 as the touch control signals, but the signals are merely examples. Various kinds of touch control signals can be used in the touch screen device 200 without being limited thereto.

The first transient voltage suppressor D1 has one end that is connected to a wire for a first power source voltage VCC1 which is applied from the second connector 211 to the touch controller 221. The other end is connected to the ground power source GND. The first transient voltage suppressor D1 can be a transient voltage suppressor (TVS) diode or a zener diode.

The second transient voltage suppressor D2 has one end that is connected to a wire for a second power source voltage VCC2 which is applied from the second connector 211 to the touch controller 221. The other end is connected to the ground power source GND. One of the first and second power source voltages VCC1 and VCC2 supplies power to a logic circuit of the touch controller 221, and the other power source voltage supplies a driving power of the touch controller 221. Similarly, the second transient voltage suppressor D2 can be a TVS diode or a zener diode.

The third transient voltage suppressor D3 has one end that is connected to a wire for an event signal ATTN which is applied from the second connector 211 to the touch controller 221. The other end is connected to the ground power source GND. The third transient voltage suppressor D3 can also be a TVS diode or a zener diode.

The first to third transient voltage suppressors D1 to D3 discharge an overcurrent caused by electrical overstress or electrostatic discharge that is generated at the outside to the corresponding power source GND.

Therefore, it is possible to prevent the touch controller 221 from being damaged by the electrical overstress or the electrostatic discharge that is momentarily generated.

The first and second sensing wires 33t and 33r and the ground wires GND1 and GND2 are connected to the touch controller 221. The first and second sensing wires 33t and 33r and the ground wires GND1 and GND2 are formed on the second flexible printed circuit substrate 210 so as to be connected to the touch substrate 230. Therefore, the first and second sensing wires 33t and 33r and the ground wires GND1 and GND2 are connected to the touch controller 221. In FIG. 6 and FIG. 7, six first sensing wires 33t and six second sensing wires 33r are illustrated for convenience of illustration, but the number of the first and second sensing wires 33t and 33r and a disposition order thereof are not limited thereto.

The touch controller 221 applies the touch detection signal to the first sensing wires 33t. The touch controller 221 receives the sensing signal through the second sensing wires 33r. The touch controller 221 can detect a touch position by measuring a change of the capacitance of the sensing electrodes 32 from the sensing signal that is received in response to the touch detection signal applied to the first sensing wires 33t.

A fourth and fifth transient voltage suppressor D4 and D5 are respectively connected to the ground wires GND1 and GND2 on the second flexible printed circuit substrate 210. One ends of the ground wires GND1 and GND2 that are formed in the loop-like shape are connected to the touch controller 221. The fourth and fifth transient voltage suppressors D4 and D5 are respectively connected to the ground wire GND1 and the ground wire GND2.

The fourth transient voltage suppressor D4 has one end that is connected to the ground wire GND1 and the other end that is connected to the ground power source GND. The fourth transient voltage suppressor D4 can be a TVS diode or a zener diode.

The fifth transient voltage suppressor D5 D4 has one end that is connected to the ground wire GND2 and the other end that is connected to the ground power source GND. Similarly, the fifth transient voltage suppressor D5 can be a TVS diode or a zener diode.

Therefore, it is possible to prevent the touch controller 221 from being damaged by an overcurrent caused by electrical overstress or electrostatic discharge that is momentarily generated from the touch substrate 230.

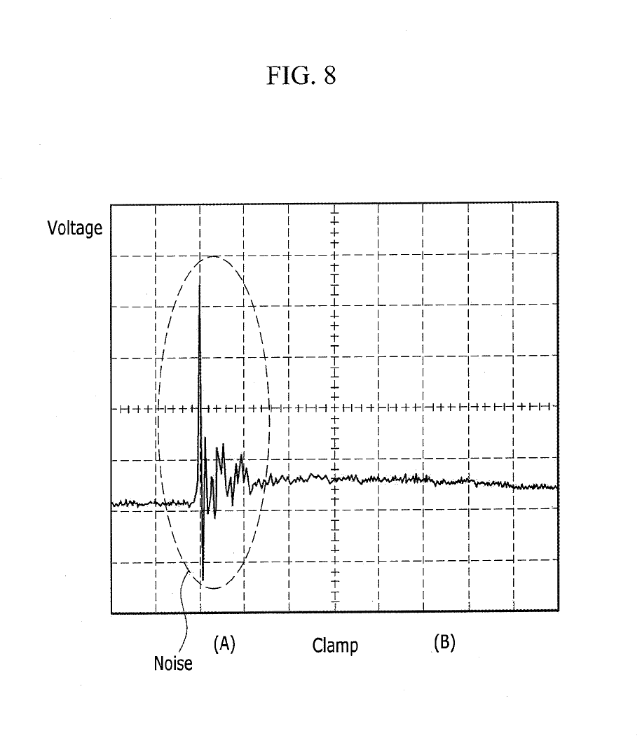

FIG. 8 is a graph illustrating a test result of measuring the noise of a signal before and after passing through the clamping circuit 222 in the touch screen device 200 according to an exemplary embodiment.

As shown in FIG. 8, a test was performed assuming that the noise of a signal is generated by an overcurrent caused by an electrical overstress or electrostatic discharge. The noise is significantly reduced after the signal passes through the clamping circuit 222 (see region “B” of the graph) compared to before the signal passes through the clamping circuit 222 (see region “A” of the graph). As a result, it is possible to prevent the touch screen device from being affected by an overcurrent caused by an electrical overstress or electrostatic discharge that is momentarily generated by additionally mounting the clamping circuit 222 and the transient voltage suppressor such as a TVS diode or a zener diode.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, those skilled in the art will understand that various modifications and other equivalent embodiments of the present invention are possible. Consequently, the true technical protective scope of the present invention must be determined based on the technical spirit of the appended claims.

What is claimed is:

1. A display device comprising:
a display substrate including a plurality of pixels and having a front surface;
a touch substrate formed over the front surface;
a flexible printed circuit substrate electrically connected to the touch substrate; and
a touch driver formed over the flexible printed circuit substrate and comprising:
a touch controller configured to receive a touch control signal;
a clamping circuit configured to substantially block an overcurrent voltage having a voltage level substantially equal to or higher than a predetermined clamping voltage; and
at least one transient voltage suppressor (TVS) electrically connected to i) at least one voltage source including a voltage applied to the touch controller and ii) an electrical ground so as to discharge the overcurrent.

2. The display device of claim 1, wherein the touch controller includes a logic circuit, and wherein the at least one voltage source includes:
first and second voltage sources configured to respectively supply voltages to the logic circuit and the touch controller except for the logic circuit.

3. The display device of claim 2, wherein the at least one TVS includes a first TVS diode electrically connected to the first voltage source and the electrical ground.

4. The display device of claim 3, wherein the at least one TVS further includes a second TVS diode electrically connected to the second voltage source and the electrical ground.

5. The display device of claim 4, further comprising:
a third TVS diode electrically connected to an event signal wire and the electrical ground, wherein the event signal wire is configured to transfer an event signal to the touch controller.

6. The display device of claim 1, wherein the touch substrate includes:
a plurality of driving electrodes;
a plurality of sensing electrodes;
a plurality of first sensing wires electrically connected to the driving electrodes;
a plurality of second sensing wires electrically connected to the sensing electrodes; and
a ground wire having a loop-like shape and formed at an outer region of the driving electrodes and the sensing electrodes.

7. The display device of claim 6, wherein the first and second sensing wires and the ground wire are electrically connected to the touch controller.

8. The display device of claim 7, further comprising:
a fourth TVS diode electrically connected to one end of the ground wire and the electrical ground.

9. The display device of claim 8, further comprising:
a fifth TVS diode electrically connected to the other end of the ground wire and the electrical ground.

10. A touch screen device comprising:
a touch substrate including a plurality of driving electrodes and a plurality of sensing electrodes; and
a touch driver electrically connected to the touch substrate,
wherein the touch driver comprises:
a touch controller configured to receive a touch control signal;
a clamping circuit configured to substantially block an overcurrent voltage having a voltage level substantially equal to or higher than a predetermined clamping voltage; and
at least one transient voltage suppressor (TVS) electrically connected to i) at least one voltage source including a voltage applied to the touch controller and ii) an electrical ground so as to discharge the overcurrent.

11. The touch screen device of claim 10, wherein the touch controller includes a logic circuit, and wherein the voltage source includes:
first and second voltage sources configured to respectively supply voltages to the logic circuit and the touch controller except for the logic circuit.

12. The touch screen device of claim 11, wherein the at least one TVS includes a first TVS diode electrically connected to the first voltage source and the electrical ground.

13. The touch screen device of claim 12, wherein the at least one TVS further includes a second TVS diode electrically connected to the second voltage source and the electrical ground.

14. The touch screen device of claim 13, further comprising:
a third TVS diode electrically connected to an event signal wire and the electrical ground, wherein the event signal wire is configured to transfer an event signal to the touch controller.

15. The touch screen device of claim 14, wherein the touch substrate further includes:
a plurality of first sensing wires electrically connected to the driving electrodes;
a plurality of second sensing wires electrically connected to the sensing electrodes; and
a ground wire having a loop-like shape and formed at an outer region of the driving electrodes and the sensing electrodes,
wherein the first and second sensing wires and the ground wire are electrically connected to the touch controller.

16. The touch screen device of claim 15, further comprising:
a fourth TVS diode electrically connected to one end of the ground wire and the electrical ground.

17. The touch screen device of claim 16, further comprising:
a fifth TVS diode electrically connected to the other end of the ground wire and the electrical ground.

18. A touch driver for controlling a driving of a touch screen device, the touch driver comprising:
a touch controller configured to receive a touch control signal;
a clamping circuit configured to substantially block an overcurrent voltage having a voltage level substantially equal to or higher than a predetermined clamping voltage; and
at least one transient voltage suppressor (TVS) electrically connected to i) at least one voltage source including a voltage applied to the touch controller and ii) an electrical ground so as to discharge the overcurrent.

19. The touch driver of claim 18, wherein the at least one TVS includes:
a first TVS diode electrically connected to the first voltage source and the electrical ground; and
a second TVS diode electrically connected to the second voltage source and the electrical ground.

20. The touch driver of claim 19, further comprising:
a third TVS diode electrically connected to an event signal wire and the electrical ground, wherein the event signal wire is configured to transfer an event signal to the touch controller.
